(19) United States
(12) Patent Application Publication
(10) Pub. No.: US 2010/0213564 A1
(43) Pub. Date: Aug. 26, 2010

(54) SENSOR CHIP AND METHOD OF MANUFACTURING THE SAME

(75) Inventors: Kazumasa Tanida, Kawasaki-shi (JP); Hideo Numata, Yokohama-shi (JP); Eiji Takano, Yokohama-shi (JP)

Correspondence Address: TUROCY & WATSON, LLP, 127 Public Square, 57th Floor, Key Tower, CLEVELAND, OH, 44114, US

(73) Assignee: KABUSHIKI KAISHA TOSHIBA, Tokyo (JP)

(21) Appl. No.: 12/556,613

(22) Filed: Sep. 10, 2009

(30) Foreign Application Priority Data
Feb. 26, 2009 (JP) 2009-044523

(51) Int. Cl. H01L 31/0216; H01L 31/18

(52) U.S. Cl. 257/435; 438/69; 257/E31.12

(57) ABSTRACT

A sensor chip includes: a semiconductor substrate that is provided with a light receiving portion on a main surface; a light transmissive member that is provided on the main surface of the semiconductor substrate, enclosing a hollow portion above the light receiving portion, to surround upper and periphery of the light receiving portion; and a light transmissive protective member that is provided on the light transmissive member.

### RELATED APPLICATION(S)

The present disclosure relates to the subject matter contained in Japanese Patent Application No. 2009-044523 filed on Feb. 26, 2009, which is incorporated herein by reference in its entirety.

### FIELD

The present invention relates to a sensor chip and a method of manufacturing the sensor chip.

### BACKGROUND

Sensor chips provided with CCDs (Charge Coupled Device) or CMOS (Complementary metal-Oxide Semiconductor) image sensors have been widely used in electronic apparatuses such as digital cameras and camera-equipped mobile phones. Recently, these apparatuses have become small and light, thereby requiring sensor chips mounted on the electronic apparatuses to be small and light. As a technique to make the sensor chips small and light, a chip size package (hereinafter, referred to as “CSP” has been proposed. An example of such technique is disclosed in WO 2005/022631 A1 (counterpart U.S. publication is: US 7180149 B1).

In the CSP, for example, a semiconductor substrate has a light receiving portion formed of an image element such as a CCD and a CMOS sensor on a front surface and has an external terminals on a rear surface, a through hole passing through the front and back surfaces is formed in the semiconductor substrate, and a conductive layer is formed in the through hole. A color filter and a micro lens for collecting light is formed on the light receiving portion. A plurality of light receiving portions and external terminals are formed on a semiconductor wafer, and become individual sensor chips by a dicing process. In the production process, a sensor chip has been proposed, which is provided with a light transmissive protective member (e.g., glass substrate) formed to cover an area including the light receiving portion to protect the light receiving portion formed on the surface of the semiconductor substrate from dust and the like (e.g., WO 2005/022631 A1, FIG. 3A). According to the sensor chip, a light receiving portion is provided with an adhesive layer in a pattern having an opening portion above the light receiving portion on the semiconductor surface, and a light transmissive protective member is adhered to the semiconductor substrate through the adhesive layer. Accordingly, a sensor chip provided with a gap above the light receiving portion between the light transmissive protective member and the semiconductor substrate is formed. The light transmissive protective member is formed of an inorganic material such as glass. The adhesive layer is formed of an organic material such as polyimide resin.

### SUMMARY

According to a first aspect of the invention, there is provided a sensor chip including: a semiconductor substrate that is provided with a light receiving portion on a main surface; a light transmissive member that is provided on the main surface of the semiconductor substrate, enclosing a hollow portion above the light receiving portion, to surround upper and periphery of the light receiving portion; and a light transmissive protective member that is provided on the light transmissive member.

According to a second aspect of the invention, there is provided a sensor chip including: a semiconductor substrate that has a first surface and a second surface, the semiconductor substrate being provided with a light receiving portion on the first surface; a light transmissive member that is provided on the second surface of the semiconductor substrate, enclosing a hollow portion above an area corresponding to the light receiving portion, to surround upper and periphery of an area on the second surface of the semiconductor substrate corresponding to the light receiving portion; and a light transmissive protective member that is provided on the light transmissive member.

According to a third aspect of the invention, there is provided a method for manufacturing a sensor chip, the method including: forming a light receiving portion on a main surface of a semiconductor substrate; and adhering a light transmissive protective member to the semiconductor substrate through a protruding portion, the light transmissive member having the protruding portion and being configured to surround upper and periphery of the light receiving portion.

### BRIEF DESCRIPTION OF THE DRAWINGS

A general configuration that implements the various feature of the invention will be described with reference to the drawings. The drawings and the associated descriptions are provided to illustrate embodiments of the invention and not to limit the scope of the invention.

FIG. 1 is a sectional view of a sensor chip according to a first embodiment of the present invention.

FIG. 2 is a sectional view for describing a manufacturing process of the sensor chip according to the first embodiment of the present invention.

FIG. 3 is a sectional view for describing a manufacturing process of the sensor chip according to the first embodiment of the present invention.

FIG. 4 is a sectional view for describing a manufacturing process of the sensor chip according to the first embodiment of the present invention.

FIG. 5 is a sectional view for describing a manufacturing process of the sensor chip according to the first embodiment of the present invention.

FIG. 6 is a sectional view for describing a manufacturing process of the sensor chip according to the first embodiment of the present invention.

FIG. 7 is a sectional view for describing a manufacturing process of the sensor chip according to the first embodiment of the present invention.

FIG. 8 is a sectional view for describing a manufacturing process of the sensor chip according to the first embodiment of the present invention.

FIG. 9 is a sectional view of a sensor chip according to a second embodiment of the present invention.

FIG. 10 is a sectional view of a sensor chip according to a second embodiment of the present invention.

FIG. 11 is a sectional view for describing a manufacturing process of the sensor chip according to the third embodiment of the present invention.

FIG. 12 is a sectional view for describing a manufacturing process of the sensor chip according to the third embodiment of the present invention.

FIG. 13 is a sectional view for describing a manufacturing process of the sensor chip according to the third embodiment of the present invention.

FIG. 14 is a sectional view for describing a manufacturing process of the sensor chip according to the third embodiment of the present invention.

FIG. 15 is a sectional view for describing a manufacturing process of the sensor chip according to the third embodiment of the present invention.

FIG. 16 is a sectional view for describing a manufacturing process of the sensor chip according to the third embodiment of the present invention.

FIG. 17 is a sectional view for describing a manufacturing process of the sensor chip according to the third embodiment of the present invention.

FIG. 18 is a sectional view for describing a manufacturing process of the sensor chip according to the third embodiment of the present invention.

FIG. 19 is a sectional view for describing a manufacturing process of the sensor chip according to the third embodiment of the present invention.

FIG. 20 is a sectional view for describing a manufacturing process of the sensor chip according to the third embodiment of the present invention.

### DETAILED DESCRIPTION OF THE EMBODIMENT(S)

Hereinafter, embodiments of the invention will be described with reference to the drawings. In the following description, common reference numerals are assigned to common components and elements throughout the drawings.

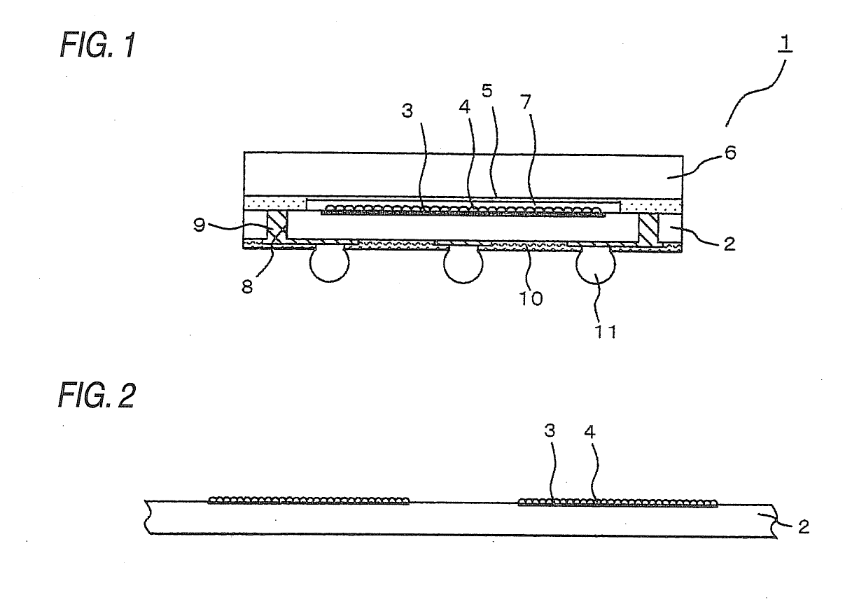

FIG. 1 is a cross-sectional view illustrating a sensor chip 1 according to a first embodiment of the invention. FIG. 2 to FIG. 8 are cross-sectional views illustrating a part of a production process of the sensor chip 1 according to the first embodiment of the invention.

A light receiving portion 3 having a photo diode, a transistor, and the like, is provided on a first surface (an upper surface of a semiconductor substrate 2 in FIG. 1) of a semiconductor substrate 2 of a sensor chip 1. An active element area (not shown) formed of a wiring circuit connecting the photo diode, the transistor of the light receiving portion 3, and the like is provided on the first surface of the semiconductor substrate 2. A plurality of electrodes (not shown) are provided on the first surface of the semiconductor substrate 2. The plurality of electrodes are electrically connected to the active element area and the light receiving portion 3, and provide input/output signals and supply electric power to the active element area and the light receiving portion 3. The light receiving portion 3, the active element area, and the electrodes constitute a so-called image sensor.

A through hole 8 passing through the first surface and the second surface (a lower surface of the semiconductor substrate 2 in FIG. 1) of the semiconductor substrate 2 is formed in the semiconductor substrate 2, and an insulating film (not shown) is formed from an inner wall surface of the through hole 8 over the second surface of the semiconductor substrate 2. A penetration wiring layer 9 is formed in the through hole 8. The penetration wiring layer 9 electrically connects external terminals 11 (e.g., solder ball) formed on the second surface to the electrode (not shown) formed on the first surface of the semiconductor substrate 2. An area other than the external terminals 11 formed on the second surface of the semiconductor substrate 2 is covered with a protective film 10.

A color filter (not shown), an over-coat film (not shown), and a micro lens 4 are formed on the light receiving portion 3 formed on the first surface of the semiconductor substrate 2. Generally, the color filter, the over-coat film, and the micro lens 4 are formed of organic materials.

A light transmissive member 5 is formed on the first surface of the semiconductor substrate 2 to surround upper and periphery of the light receiving portion 3. Accordingly, a hollow portion 7 is formed above the light receiving portion 3 between the semiconductor substrate 2 and the light transmissive member 5. A light transmissive protective member 6 is formed on the light transmissive member 5. As described above, the light transmissive member 5 is formed on the main surface of the semiconductor substrate 2 to surround upper and periphery of the light receiving portion 3, and the light transmissive protective member 6 is formed on the light transmissive member 5, thereby covering the whole side of the hollow portion 7 close to the light transmissive protective member 6 with the light transmissive member 5. For this reason, in the hollow portion 7, the interface between the light transmissive protective member 6 and the light transmissive member 5 is not exposed. Accordingly, it is possible to solve the problems, for example, peeling-off which occurs from an angled portion of an interface between the light transmissive protective member and the light transmissive member (adhesive layer) when an inner pressure of a hollow portion is increased in a high-vacuum process such as a dry etching method, a CVD method, and a sputtering method,. As a result, the yield is decreased.

The light transmissive member 5 formed of the organic material is bonded to the first surface of the semiconductor substrate 2 through the color filter, the over-coat film, the micro lens 4, and the like formed of the organic materials on the first surface of the semiconductor substrate 2. For this reason, the bonding between the first surface of the semiconductor substrate 2 and the light transmissive member 5 is a bonding between organic material and organic material, and thus adhesion between the first surface of the semiconductor substrate 2 and the light transmissive member 5 is satisfactory.

The light transmissive member 5 may or may not have adhesion to the first surface of the semiconductor substrate 2. When the light transmissive member 5 has the adhesion, the light transmissive member 5 is directly adhered to the first surface of the semiconductor substrate 2 by thermal pressing, UV adhesion, or the like. When the light transmissive member 5 does not have the adhesion, the light transmissive member 5 is adhered to the first surface of the semiconductor substrate 2 through, for example, an adhesive formed of epoxy-based resin, polyimide-based resin, acryl-based resin, or the like.

Generally, adhesion between an organic material and an inorganic material (per unit area) is low. However, in the embodiment, the light transmissive member 5 formed of the organic material and the light transmissive protective member 6 formed of the inorganic material are adhered to each other, because the interface between the light transmissive member 5 and the light transmissive protective member 6 have wider area as compared with the past.

Preferably, the light transmissive member 5 has a refractive index substantially equal to the refractive index of the light transmissive protective member 6. Specifically, the difference between the refractive index of the light transmissive member 5 and the refractive index of the light transmissive protective member 6 is preferably within 0.1. The light transmissive member 5 is provided to cover the light receiving portion 3, with the light transmissive protective member 6. For this reason, light or electrons pass through the light transmissive member 5 and the light transmissive protective member 6 and enter the light receiving portion 3. When the refractive index of the light transmissive member 5 and the refractive index of the light transmissive protective member 6 are substantially equal to each other, it is not necessary to consider the refraction and reflection of incident light in the adhered face (interface) of the light transmissive member 5 and the light transmissive protective member 6. Accordingly, a known optical design can be used. Even when the difference between the refractive index of the light transmissive member 5 and the refractive index of the light transmissive protective member 6 is not within 0.1, it is possible to optimize the optical design if optical characteristics such as the refractive index of the light transmissive member 5 are known Next, a method of producing the sensor chip according to the embodiment will be described with reference to FIG. 2 to FIG. 8. FIG. 2 to FIG. 8 show a process of producing two individual sensor chips, in which two sensor chips are formed on the same semiconductor substrate 2 at once and the two sensor chips are made into individual chips.

First, as shown in FIG. 2, the light receiving portion 3 has a photo diode or a transistor and the active element area (not shown) formed of a wiring circuit for connecting the photo diode, the transistor, or the like are formed on the first surface of the semiconductor substrate 2. The plurality of electrodes (not shown) for inputting and outputting electrical signals or supplying electric power are formed in the vicinity of the light receiving portion 3 and the active element area, and the electrodes are electrically connected to the light receiving portion 3 and the active element area. Then, the color filter (not shown), the over-coat film (not shown), and the micro lens 4 made of organic materials are formed on the first surface of the semiconductor substrate 2.

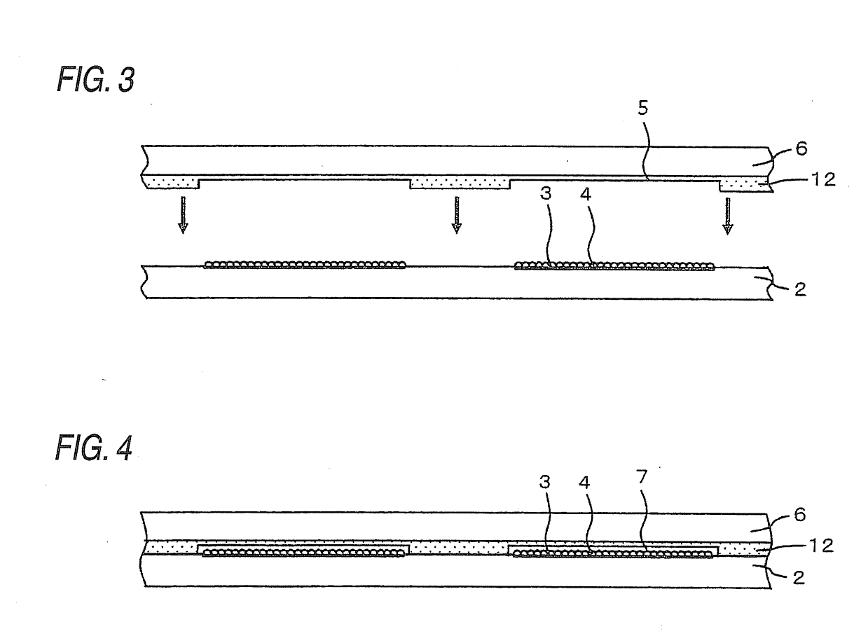

Next, as sequentially shown in FIG. 3 and FIG. 4, the light transmissive protective member 6 provided with the light transmissive member 5 on the surface thereof is adhered to the first surface of the semiconductor substrate 2 through the light transmissive member 5. The light transmissive member 5 is provided with a protruding portion 12 on the surface thereof to surround upper and periphery of the light receiving portion 3. The light transmissive protective member 6 is provided with the light transmissive member 5 having the protruding portion 12 on the surface thereof, and is adhered to the semiconductor substrate 2 through the protruding portion 12. Accordingly, the hollow portion 7 is formed on the light receiving portion 3 between the light transmissive member 5 and the semiconductor substrate 2.

The light transmissive member 5 may or may not have adhesion to the first surface of the semiconductor substrate 2. When the light transmissive member 5 has adhesion to the first surface of the semiconductor substrate 2, the protruding portion 12 of the light transmissive member 5 is directly adhered to the first surface of the semiconductor substrate 2 by thermal pressing, UV adhesion, or the like. When The light transmissive member 5 does not have the adhesion to the first surface of the semiconductor substrate 2e, the protruding portion 12 of the light transmissive member 5 and the first surface of the semiconductor substrate 2 are adhered to each other through the adhesive formed of epoxy-based resin, polyimide-based resin, acryl-based resin, or the like.

The light transmissive member 5 may be formed by a dry etching method or a wet etching method, for example, using a pattern mask When the light transmissive member 5 is formed of an organic material, an inorganic material, an organic-inorganic hybrid material, or the like having photosensitivity, the light transmissive member 5 may formed by lithography. When the light transmissive member 5 is formed of an organic material, an inorganic material, an organic-inorganic hybrid material, or the like having a light curing property, the light transmissive member 5 may be formed by a UV imprint method or a thermal imprint method, using a stamp mask.

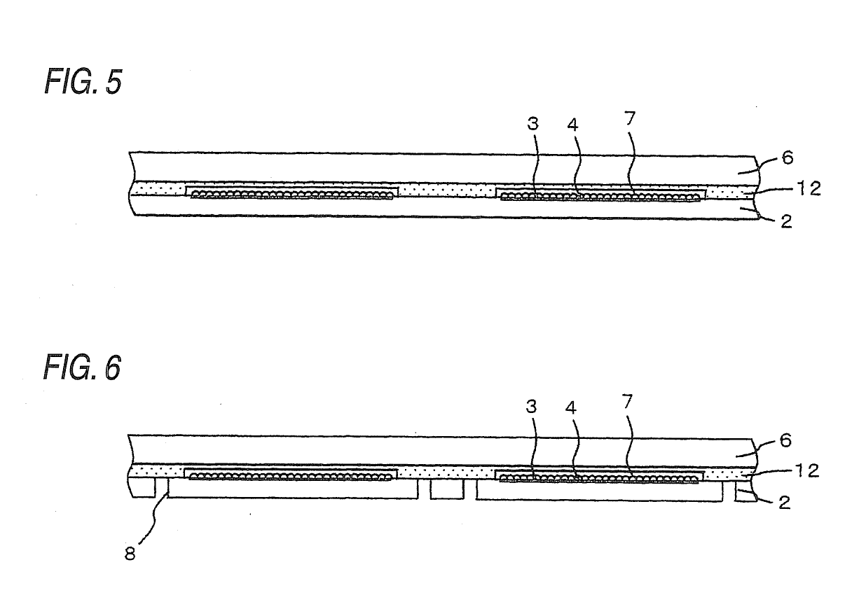

Next, as shown in FIG. 5, the second surface of the semiconductor substrate 2 is etched by mechanical polishing, chemical mechanical polishing, wet etching, dry etching, or the like, thereby making the semiconductor substrate 2 thin. Accordingly, the thickness of the semiconductor substrate 2 becomes about 50 μm to 150 μm.

Next, as shown in FIG. 6, the through holes 8 are formed from the second surface of the semiconductor substrate 2 by a plasma etching method, using a pattern mask. Accordingly, the electrodes formed on the first surface of the semiconductor substrate 2 are exposed from the through hole 8.

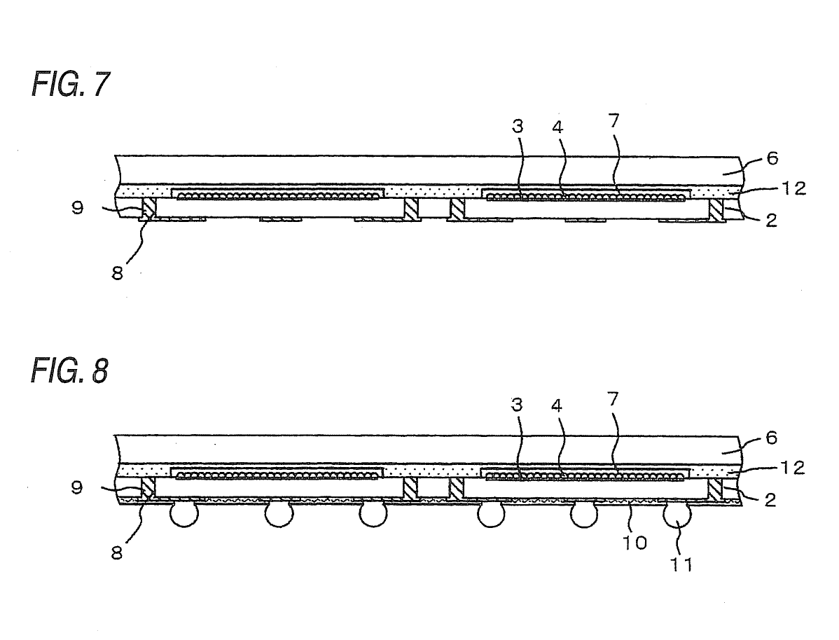

Next, as shown in FIG. 7, the penetration wiring layer 9 coming in contact with the inside of the electrodes exposed from the through holes 8 and formed over the second surface of the semiconductor substrate 2 is formed by a sputtering method, a CVD method (Chemical Vapor Deposition Method), an evaporation method, a plating method, or a printing method, using a pattern mask. The penetration wiring layer 9 are formed of, for example, a high resistance metal material (Ti, TiN, TiW, Ni, NiV, NiFe, Cr, TaN, CoWP, etc.), a low resistance metal material (Al, Al—Cu, Al—Si—Cu, Cu, Au, Ag, solder material, etc.), or conductive resin in a single-layered or a multi-layered form. An insulating layer (not shown) is formed between the penetration wiring layer 9 and the semiconductor substrate 2 from the inside of the through holes 8 over the second surface of the semiconductor substrate 2 to insulate the penetration wring layer 9 and the semiconductor substrate 2.

Next, as shown in FIG. 8, the external terminals 11 are formed in contact with the penetration wiring layer 9 on the second surface of the semiconductor substrate 2. The external terminals 11 are formed of, for example, a solder material. The protective film 10 is formed in an area other than the external terminals 11 on the second surface of the semiconductor substrate 2. The protective film 10 is formed of, for example, polyimide resin, epoxy resin, or solder resist. Then, the semiconductor substrate 2, the light transmissive member 5, and the light transmissive protective member 6 are cut by a cutting blade of a dicer, thereby obtaining the individual sensor chip 1 shown in FIG. 1.

According to the method of producing the sensor chip according to the embodiment, the light transmissive member 5 is formed on the surface of the light transmissive protective member 6 in advance. Accordingly, even when the forming of the light transmissive member 5 fails, the light transmissive member 5 formed on the light transmissive protective member 6 made of the inorganic material can be easily peeled off, washed, and reworked by organic peeling-off solution or the like.

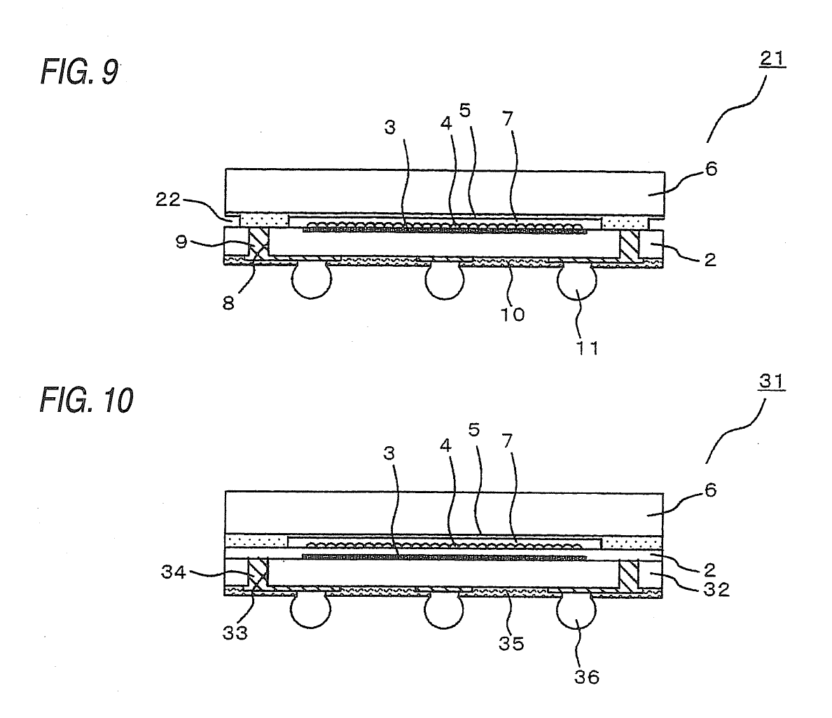

FIG. 9 is a cross-sectional view illustrating a sensor chip 21 according to a second embodiment of the invention. The same reference numerals and symbols are given to the same configurations as those of the sensor chip 1 according to the first embodiment, and the description thereof is omitted.

In the sensor chip 21 according to the second embodiment, the light transmissive member 5 is formed on the main surface of the semiconductor substrate 2 to surround upper and periphery of the light receiving portion 3, the light transmissive protective member 6 is additionally formed on the light transmissive member 5, the whole side of the hollow portion 7 close to the light transmissive protective member 6 is covered with the light transmissive member 5, thereby solving the known problem of decreased yield. In this point, the sensor chip 21 is the same as the sensor chip 1 according to the first embodiment.

The sensor chip 21 according to the second embodiment is different from the sensor chip 1 according to the first embodiment in that the light transmissive member 5 is provided with a gap 22 between the semiconductor substrate 2 and the light transmissive member 5 in the outer peripheral area. In addition, the light transmissive member 5 is formed on the outer peripheral edge of the light transmissive protective member 6 as well as the case of first embodiment.

With such a configuration, the following advantages are obtained. That is, the light transmissive member 5 is provided with the gap 22 in the outer peripheral area, as shown in FIG. 8 of the description of the method of producing the sensor chip 1 according to the first embodiment, and the semiconductor substrate 2, the light transmissive member 5, and the light transmissive protective member 6 are cut in the position of the gap 22 in the case of separating the sensor chips formed on the same substrate by the dicer, thereby reducing the thickness of the light transmissive member 5 at the cut parts. Accordingly, it is possible to suppress loading caused when the cutting blade used for cutting cuts the light transmissive member 5, and thus it is possible to improve the yield.

The light transmissive member 5 is formed on the outer peripheral edge of the light transmissive protective member 6 as well as the case of first embodiment, thereby covering the inside of the gap 22 close to the light transmissive protective member 6 with the light transmissive member 5, and the interface between the light transmissive protective member 6 and the light transmissive member 5 is not exposed in the gap 22. Accordingly, it is possible to solve the problems that the peeling-off occurs from the angled portion of the interface between the light transmissive protective member and the adhesion layer, the light transmissive protective member comes out of the semiconductor substrate, and the yield is decreased. Therefore, it is possible to further improve the yield.

The method of producing the sensor chip according to the second embodiment of the invention is the same as the method of producing the sensor chip according to the first embodiment of the invention. In the process of the method of producing the sensor chip according to the first embodiment shown in FIG. 3, it is possible to produce the sensor chip 21 according to the second embodiment by using the light transmissive member 5 provided with the gap 22 at the protruding portion 12 shown in FIG. 9. In addition, in the method of producing the sensor chip according to the second embodiment, it is possible to obtain the same advantages as the advantages obtained by the method of producing the sensor chip according to the first embodiment.

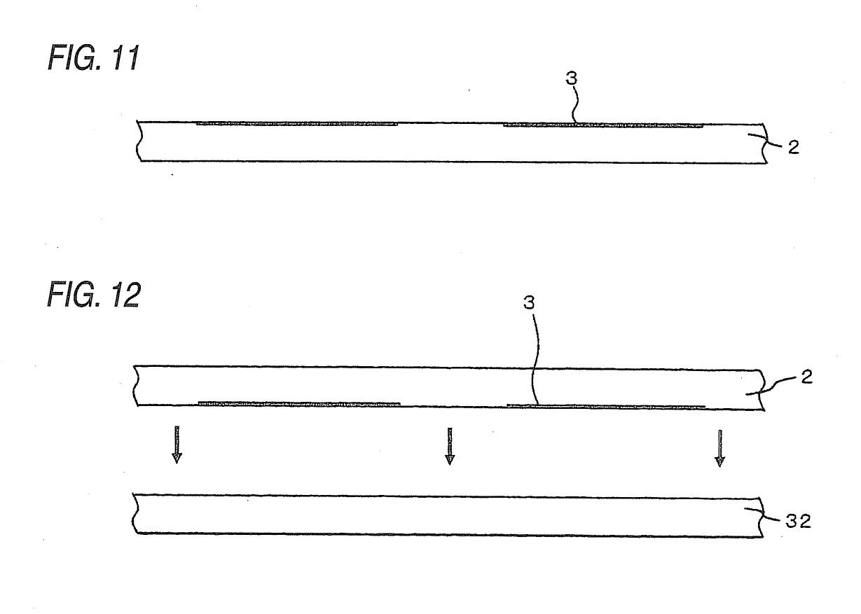

FIG. 10 is a cross-sectional view illustrating a sensor chip 31 according to a third embodiment of the invention. FIG. 11 to FIG. 20 are cross-sectional views illustrating a part of a method of producing a sensor chip according to the third embodiment of the invention. The same reference numerals and symbols are given to the same configurations as those of the sensor chip 1 according to the first embodiment, and the description thereof is omitted.

The embodiment is an example of using a back-side-illuminated imaging element as an image element mounted on the sensor chip according to the invention.

The light receiving portion 3 provided with a photo diode, a transistor, and the like is provided on the first surface (a lower surface of the semiconductor substrate 2 in FIG. 10) of the semiconductor substrate 2. An active element area (not shown) formed of a wiring circuit connecting the photo diode, the transistor, and the like of the light receiving portion 3 is provided on the first surface of the semiconductor substrate 2. The light receiving portion 3 and a plurality of electrodes (not shown) electrically connected to the active element area, inputting and outputting electrical signals, and supplying electric power are provided on the first surface of the semiconductor substrate 2. The light receiving portion 3 receives energy rays such as light and electrons entering the second surface (an upper surface of the semiconductor substrate 2 in FIG. 10) of the semiconductor substrate 2 and passing through the semiconductor substrate 2. The light receiving portion 3, the active element area, and the electrodes constitute a so-called back-side-illuminated image sensor.

A support member 32 having a through hole 33 is bonded onto the first surface of the semiconductor substrate 2, and an insulating film (not shown) is formed from the inner wall surface of the through hole 33 over the surface of the support member 32. A penetration wiring layer 34 is formed in the through hole 33. The penetration wiring layer 34 electrically connects an external terminals 36 (e.g., solder ball) formed on the surface of the support member 32 to the electrode (not shown) formed on the first surface of the semiconductor substrate 2. An area of the surface of the support member 32 other than the external terminals 36 is covered with a protective film 35.

The color filter (not shown), the over-coat film (not shown), and the micro lens 4 are formed on the second surface of the semiconductor substrate 2. Generally, the color filter, the over-coat film, and the micro lens 4 are formed of organic materials.

The light transmissive member 5 is formed on the second surface of the semiconductor substrate 2 to surround the periphery and an upper part of an area corresponding to the light receiving portion 3. “Corresponding” means a relationship between an area where the light receiving portion 3 is formed on the first surface of the semiconductor substrate and an area on the second surface of the semiconductor substrate provided on the back surface of the area. Accordingly, the hollow portion 7 is formed above the area corresponding to the light receiving portion 3 between the semiconductor substrate 2 and the light transmissive member 5. The light transmissive protective member 6 is formed parallel to the light transmissive member 5 on the light transmissive member 5. As described above, the light transmissive member 5 is formed on the main surface of the semiconductor substrate 2 to surround the periphery and the upper part of the area corresponding to the light receiving portion 3, and the light transmissive protective member 6 is additionally formed on the light transmissive member 5, thereby covering the whole side of the hollow portion 7 close to the light transmissive protective member 6 with the light transmissive member 5. For this reason, in the hollow portion 7, the interface between the light transmissive protective member 6 and the light transmissive member 5 is not exposed. Accordingly, it is possible to solve problems, for example, when an inner pressure of a hollow portion is increased in a high-vacuum process such as a dry etching method, a CVD method, and a sputtering method, peeling-off occurs from an angled portion of an interface between the light transmissive protective member and the light transmissive member (adhesive layer), the light transmissive protective member comes out of the semiconductor substrate, and the yield is decreased.

Also in the structure according to the embodiment, the light transmissive member 5 may be provided with the gap 22 between the semiconductor substrate 2 and the light transmissive member 5 in the outer peripheral area thereof, and may be formed on the outer peripheral edge of the light transmissive protective member 6, as described in second embodiment. In this case, the same advantages as those of second embodiment are obtained.

Since the back-side-illuminated imaging element is used in the sensor chip according to the embodiment, it is possible to reduce optical loss in the light receiving portion 3 as compared with the sensor chip according to the first embodiment.

Next, a method of producing the sensor chip according to the embodiment will be described with reference to FIG. 11 to FIG. 20. FIG. 11 to FIG. 20 show a process of producing two individual sensor chips, in which two sensor chips are formed on the same semiconductor substrate 2 at once and the two sensor chips are made into individual pieces.

First, as shown in FIG. 11, the light receiving portion 3 formed of a photo diode or a transistor and the active element area (not shown) formed of a wiring circuit for connecting the photo diode, the transistor, or the like are formed on the first surface of the semiconductor substrate 2. The plurality of electrodes (not shown) for inputting and outputting electrical signals or supplying electric power are formed in the vicinity of the light receiving portion 3 and the active element area, and the electrodes are electrically connected to the light receiving portion 3 and the active element area.

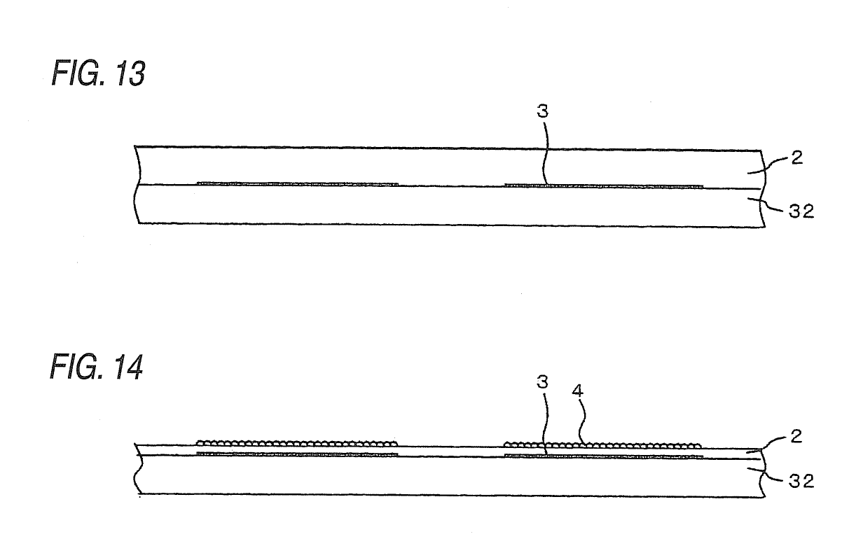

Next, as sequentially shown in FIG. 12 and FIG. 13, the first surface of the semiconductor substrate 2 is bonded to the support member 32. They may be bonded through an adhesive formed of epoxy-based resin, polyimide-based resin, acryl-based resin, or the like, and may be directly bonded by hydrogen bonding, anodized bonding, or the like. The support member 32 is formed of, for example, silicon, gallium arsenic, borosilicate glass, quartz glass, soda-lime glass, epoxy resin, polyimide resin, or the like.

Next, as shown in FIG. 14, the second surface of the semiconductor substrate 2 is etched by mechanical polishing, chemical mechanical polishing, wet etching, dry etching, or the like, thereby making the semiconductor substrate 2 thin. The semiconductor substrate 2 is made thin up to the extent that energy rays such as light and electrons entering the second surface pass through the semiconductor substrate 2 and can be collected by the photo diode of the light receiving portion 3 formed on the first surface. For this reason, the thickness of the semiconductor substrate 2 is preferably, for example, about 1 μm to 20 μm. Then, a color filter (not shown), an optical black layer (not shown), and a micro lens 4 are formed on the second surface of the semiconductor substrate 2.

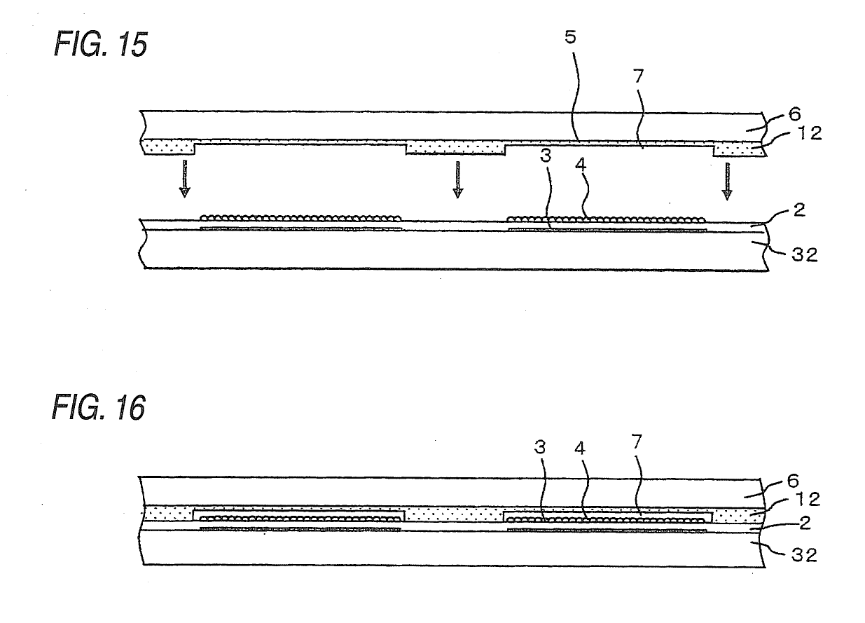

Next, as sequentially shown in FIG. 15 and FIG. 16, the light transmissive protective member 6 provided with the light transmissive member 5 on the surface thereof is adhered to the first surface of the semiconductor substrate 2 through the light transmissive member 5. The light transmissive member 5 is provided with a protruding portion 12 on the surface thereof to surround the periphery and the upper part of the light receiving portion 3. The light transmissive protective member 6 is provided with the light transmissive member 5 having the protruding portion 12 on the surface thereof, and is adhered to the semiconductor substrate 2 through the protruding portion 12. Accordingly, the hollow portion 7 is formed between the light transmissive member 5 and the area on the second surface corresponding to the light receiving portion 3 formed on the first surface of the semiconductor substrate 2.

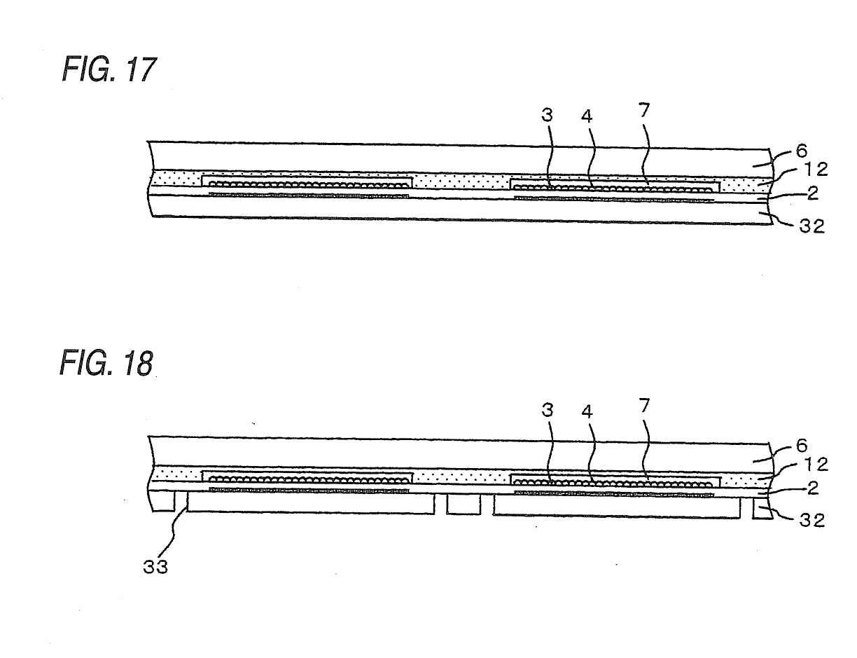

Next, as shown in FIG. 17, the surface of the support member 32 is etched by mechanical polishing, chemical mechanical polishing, wet etching, dry etching, or the like, thereby making the support member 32 thin. Accordingly, the thickness of the support member 32 becomes in a range from about 50 μm to about 150 μm.

Next, as shown in FIG. 18, the through holes 33 are formed from the surface of the support member 32 by a plasma etching method, using a pattern mask. Accordingly, the electrodes formed on the first surface of the semiconductor substrate 2 are exposed from the through hole 33.

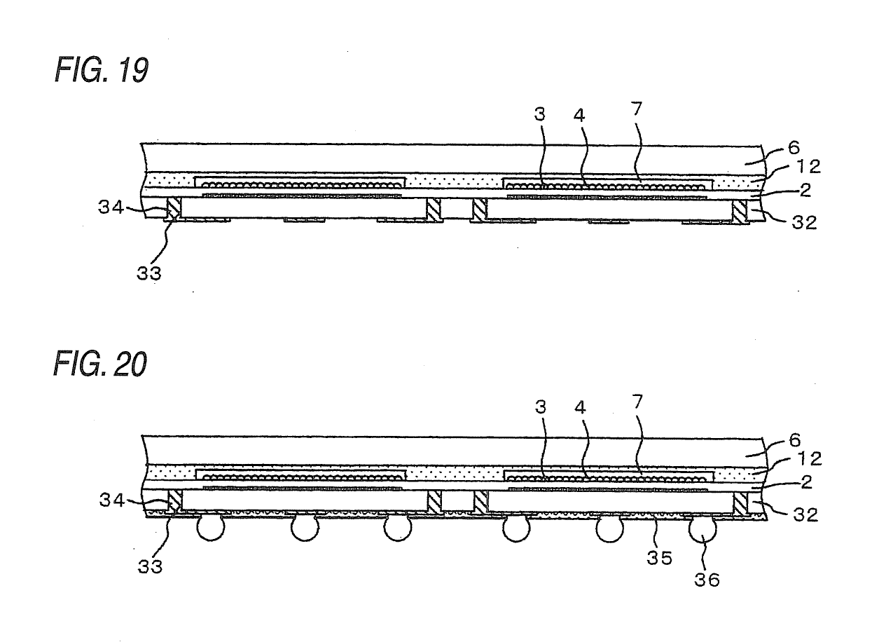

Next, as shown in FIG. 19, the penetration wiring layer 34 coming in contact with the inside of the electrodes exposed from the through holes 33 and formed over the surface of support member 32 is formed by a sputtering method, a CVD method, an evaporation method, a plating method, or a printing method, using a pattern mask. For example, when the support member 32 is formed of silicon or the like, the penetration wiring layer 34 and the support member 32 are to be insulated from each other. Accordingly, an insulating layer (not shown) is formed between the penetration wiring layer 34 and the support member 32, from the through hole 33 over the surface of the support member 32.

Next, as shown in FIG. 20, the external terminals 36 are formed in contact with the penetration wiring layer 33 on the surface of the support member 32. Then, the protective film 35 is formed in an area other than the external terminals 36 of the surface of the support member 32. Then, the support member 32, the semiconductor substrate 2, the light transmissive member 5, and the light transmissive protective member 6 are cut by a cutting blade of a dicer, thereby obtaining the individual sensor chip 31 shown in FIG. 10.

Also in the method of producing the sensor chip according to the embodiment, the same advantages as those of the method of producing the sensor chip according to the first embodiment are obtained.

It is to be understood that the present invention is not limited to the specific embodiments described above and that the present invention can be embodied with the components modified without departing from the spirit and scope of the present invention. The present invention can be embodied in various forms according to appropriate combinations of the components disclosed in the embodiments described above. For example, some components may be deleted from the configurations as described as the embodiments. Further, the components in different embodiments may be used appropriately in combination.

What is claimed is:

1. A sensor chip comprising:
a semiconductor substrate that is provided with a light receiving portion on a main surface;
a light transmissive member that is provided on the main surface of the semiconductor substrate, enclosing a hollow portion above the light receiving portion, to surround upper and periphery of the light receiving portion; and
a light transmissive protective member that is provided on the light transmissive member.

2. The sensor chip of claim 1, wherein the light transmissive member has adhesion to the main surface of the semiconductor substrate.

3. The sensor chip of claim 1, wherein a difference between a refractive index of the light transmissive member and a refractive index of the light transmissive protective member is within 0.1.

4. The sensor chip of claim 1, wherein the light transmissive member is provided with a gap above the semiconductor substrate at an outer peripheral area of the light transmissive member, and
wherein the light transmissive member extends to an outer peripheral edge of the light transmissive protective member.

5. The sensor chip of claim 2, wherein a difference between a refractive index of the light transmissive member and a refractive index of the light transmissive protective member is within 0.1.

6. The sensor chip of claim 2, wherein the light transmissive member is provided with a gap above the semiconductor substrate at an outer peripheral area of the light transmissive member, and
wherein the light transmissive member extends to an outer peripheral edge of the light transmissive protective member.

7. The sensor chip of claim 3, wherein the light transmissive member is provided with a gap above the semiconductor substrate at an outer peripheral area of the light transmissive member, and
wherein the light transmissive member extends to an outer peripheral edge of the light transmissive protective member.

8. A sensor chip comprising:
a semiconductor substrate that has a first surface and a second surface, the semiconductor substrate being provided with a light receiving portion on the first surface;
a light transmissive member that is provided on the second surface of the semiconductor substrate, enclosing a hollow portion above an area corresponding to the light receiving portion, to surround upper and periphery of an area on the second surface of the semiconductor substrate corresponding to the light receiving portion; and
a light transmissive protective member that is provided on the light transmissive member.

9. The sensor chip of claim 8, wherein the light transmissive member has adhesion to the main surface of the semiconductor substrate.

10. The sensor chip of claim 8, wherein a difference between a refractive index of the light transmissive member and a refractive index of the light transmissive protective member is within 0.1.

11. The sensor chip of claim 8, wherein the light transmissive member is provided with a gap above the semiconductor substrate at an outer peripheral area of the light transmissive member, and
wherein the light transmissive member extends to an outer peripheral edge of the light transmissive protective member.

12. The sensor chip of claim 9, wherein a difference between a refractive index of the light transmissive member and a refractive index of the light transmissive protective member is within 0.1.

13. The sensor chip of claim 9, wherein the light transmissive member is provided with a gap above the semiconductor substrate at an outer peripheral area of the light transmissive member, and
wherein the light transmissive member extends to an outer peripheral edge of the light transmissive protective member.

14. The sensor chip of claim 10, wherein the light transmissive member is provided with a gap above the semiconductor substrate at an outer peripheral area of the light transmissive member, and
wherein the light transmissive member extends to an outer peripheral edge of the light transmissive protective member.

15. A method for manufacturing a sensor chip, the method comprising:
forming a light receiving portion on a main surface of a semiconductor substrate; and
adhering a light transmissive protective member to the semiconductor substrate through a protruding portion, the light transmissive member having the protruding portion and being configured to surround upper and periphery of the light receiving portion.

16. The method of claim 15 further comprising forming the light transmissive member by a dry etching method or a wet etching method using a mask pattern.

17. The method of claim 15 further comprising forming the light transmissive member by a lithography.
